(19) United States
(12) Patent Application Publication
(10) Pub. No.: US 2018/0255654 A1
(43) Pub. Date: Sep. 6, 2018

(54) BRACKET FOR FIXING ELECTRONIC DEVICE AND MECHANISM FOR FIXING ELECTRONIC DEVICE

(71) Applicant: LSIS CO., LTD., Anyang-si (KR)

(72) Inventor: Sang-Oh JOO, Anyang-si (KR)

(21) Appl. No.: 15/868,641

(22) Filed: Jan. 11, 2018

(30) Foreign Application Priority Data
Mar. 6, 2017 (KR) 10-2017-0028245

(51) Int. Cl. H05K 5/02; H05K 5/03

(52) U.S. Cl. CPC H05K 5/0204; H05K 5/03

(57) ABSTRACT

Disclosed herein is a bracket for fixing an electronic device. The bracket for fixing an electronic device that is accommodated in an opening formed in an enclosure and has a front cover in tight contact with a front face of the enclosure in the vicinity of the opening. The bracket includes a bracket body that has an end disposed along the periphery of the rear part of the electronic device and the other end forming a support region in tight contact with the vicinity of the opening at the rear face of the enclosure, and a coupling member disposed in the bracket body to press the front cover and the supporting region against each other with the enclosure therebetween.

### CROSS-REFERENCE TO RELATED APPLICATIONS

Pursuant to 35 U.S.C. § 119(a), this application claims the benefit of earlier filing date and right of priority to Korean Patent Application No. 10-2017-0028245 filed on Mar. 6, 2017, in the Korean Intellectual Property Office, the disclosure of which is hereby incorporated by reference in its entirety.

### BACKGROUND

### Technical Field

The present disclosure relates to a bracket for fixing an electronic device, and more particularly, to a bracket capable of fixing an electronic device to an enclosure by forming a stable fixing force, and mechanism for fixing an electronic device.

### Description of the Related Art

Typically, an electronic device such as an HMI device and a panel PC has a structure fixed to an enclosure.

FIGS. 1A and 1B are views showing upper and lower ends of an existing electronic device, respectively, where slots are formed. FIG. 2 is a view showing the existing electronic device mounted on the enclosure.

Referring to FIGS. 1A and 1B, slots 11 are formed at the corners of each of the upper and lower ends of the electronic device 10.

As shown in FIG. 2, brackets 30 are disposed at the upper and lower ends of the electronic device 10.

In each of the brackets 30, a hook 32 is formed.

The hook 32 is inserted into one of the slots 11 formed at the corners of the upper and lower ends of the electronic device 10 and serves to fix the bracket 30 at that position.

Therefore, each of the brackets 30 are disposed along the periphery of the rear part of the electronic device 10 as shown in FIG. 2.

In addition, the electronic device 10 is located in an opening 21 formed in the enclosure 20 such that its front part protrudes from the front face of the enclosure 20 and its rear part protrudes from the rear face of the enclosure 20.

A screw bolt 31 is screwed into the bracket 30. Both ends of the screw bolt 31 are exposed from both ends of the bracket 30, respectively.

When the screw bolt 31 is rotated in the fastening direction by using a driver 40, the other end of the screw bolt 31 is advanced toward the rear face of the enclosure 20.

Accordingly, the other end of the screw bolt 31 gradually advances so that it may be brought into tight contact with the rear face of the enclosure 20. As a result, the both parts of the electronic device 10 can be fixed together with the enclosure 20 therebetween.

Previously, the bracket 30 is formed by plating, and thus it may be bent when a torque greater than a certain level is applied. Therefore, there is a problem that the bracket cannot fix electronic devices.

In addition, when the screw bolt 31 is screwed into the bracket 30, the other end of the screw bolt 31 comes in direct contact with the rear face of the enclosure 20. Therefore, scratches may be generated on the outer surface of the enclosure 20, or stress may be concentrated on the small contact area.

In the related art, Korean Utility Model Publication No. 20-1994-0014102 discloses a combinating device for front cabinet of electronic device.

### SUMMARY

It is an object of the present disclosure to provide a bracket capable of fixing an electronic device to an enclosure by forming a stable fixing force, and mechanism for fixing an electronic device.

According to an exemplary embodiment of the present disclosure, there is provided a bracket for fixing an electronic device.

The bracket fixes an electronic device that is accommodated in an opening formed in an enclosure and has a front cover in tight contact with the front face of the enclosure in the vicinity of the opening.

The bracket includes a bracket body that has a first end supporting a rear part of the electronic device and a second end in contact with a periphery of the rear part of the electronic device; and a coupling member disposed in the bracket body to press the front cover and the second end of the bracket body against each other from the front and rear faces of the enclosure, to fix the electronic device.

The bracket body may have a first portion having a fasting hole through which the coupling member passes, and a second portion bent from the first portion to surround the periphery of the rear part of the electronic device.

The coupling member may be coupled with the periphery of the rear part of the electronic device by being screwed, and an end of the second portion may form a supporting region in tight contact with the rear face of the enclosure near the opening

A guide hole may be formed in the periphery of the rear part of the electronic device.

A guide rod may protrude from the first portion, such that it is inserted into the guide hole to guide movement.

The guide hole may be formed in a shape conforming to the guide rod.

The longitudinal section of the guide rod may be formed in a polygonal shape.

A guide groove for guiding the movement of the second portion may be further formed on the periphery of the rear part of the electronic device.

An elastic member may be interposed between the front cover and the enclosure.

According to another exemplary embodiment of the present disclosure, there is provided mechanism for fixing an electronic device.

According to an exemplary embodiment of the present disclosure, an electronic device can be fixed to an enclosure by forming stable fixing force.

### BRIEF DESCRIPTION OF DRAWINGS

FIGS. 1A and 1B are views showing upper and lower ends of an existing electronic device, respectively, where slots are formed;

FIG. 2 is a view showing the existing electronic device mounted on the enclosure;

FIG. 3 is a perspective view showing a front face of an electronic device installed in an enclosure by brackets for fixing an electronic device according to an exemplary embodiment of the present disclosure;

FIG. 4 is a perspective view showing a rear face of an electronic device installed in an enclosure by brackets for fixing an electronic device according to an exemplary embodiment of the present disclosure;

FIG. 5 is a perspective view showing a configuration of a bracket for fixing an electronic device according to an exemplary embodiment of the present disclosure;

FIG. 6 is a perspective view showing the rear part 101 of the electronic device where the brackets are disposed;

FIG. 7 is a view showing the electronic device fixed to the enclosure by using the bracket according to the exemplary embodiment of the present disclosure;

FIG. 8 is a view showing the elastic member interposed between the front cover and the enclosure according to the exemplary embodiment of the present disclosure;

FIG. 9 is a cross-sectional view showing the bracket when it is installed;

FIG. 10 is a view showing another example of the guide member; and

FIG. 11 is a view showing an example of a guide groove formed in an outer side surface of the periphery of the rear part of the electronic device.

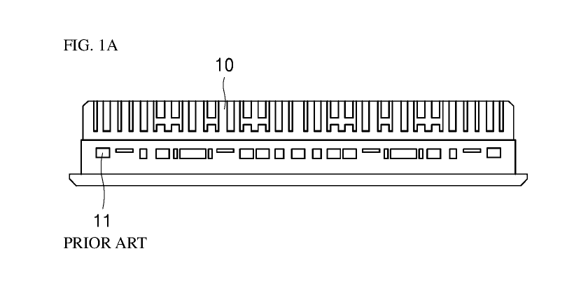

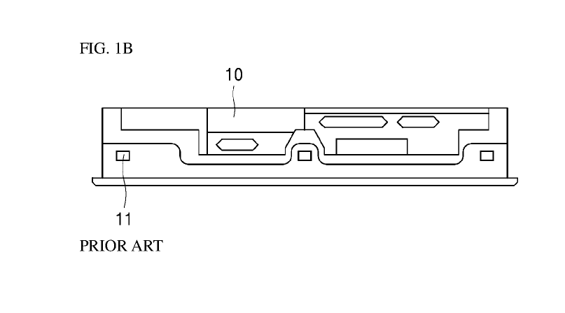

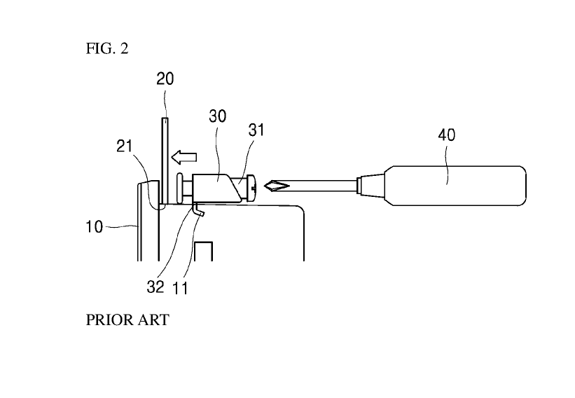

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter.

The present disclosure may, however, be embodied in many different forms and should not be construed as limited to the embodiments set forth herein.

Elements well known in the art have been omitted in order not to unnecessarily obscure the gist of the present disclosure. Like reference numerals designate like elements throughout the specification.

As used herein, when an element such as a layer, region, substrate, or panel is referred to as being “on” or “under” another element, it can be directly on or under the other element.

In addition, it does not exclude that an intervening elements may also be present between the two elements.

Hereinafter, a bracket for fixing an electronic device, and mechanism for fixing an electronic device will be described with reference to the accompanying drawings.

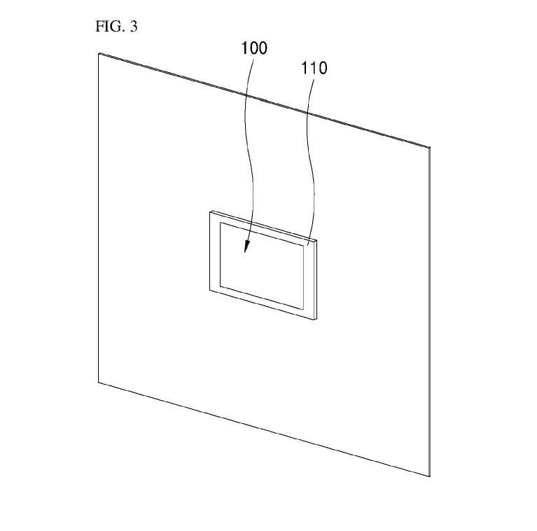

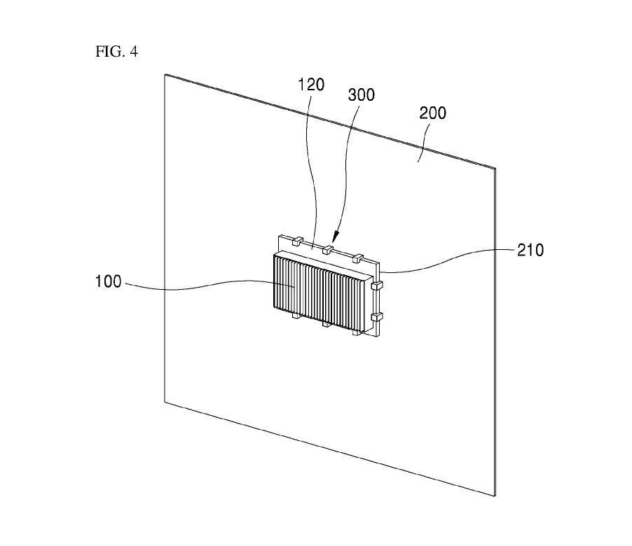

FIG. 3 is a perspective view showing a front face of an electronic device installed in an enclosure by brackets for fixing an electronic device according to an exemplary embodiment of the present disclosure. FIG. 4 is a perspective view showing a rear face of an electronic device installed in an enclosure by brackets for fixing an electronic device according to an exemplary embodiment of the present disclosure.

Referring to FIGS. 3 and 4, a bracket 300 for fixing an electronic device according to an exemplary embodiment fixes an electronic device 100 that is disposed in an opening 210 formed in an enclosure 200 and has a front cover 110 formed along the periphery in contact with the vicinity of the opening 210 at the front face of the enclosure 200.

The electronic device 100 may include an HMI device, a panel PC, etc.

The front cover 110 is formed along the periphery of the front part of the electronic device 100 and is expanded outwardly.

The electronic device 100 is fitted into the opening 210 formed in the enclosure 200.

The front cover 110 is exposed from the front face of the enclosure 200 and is in contact with the vicinity of the opening 210.

Although not shown in the drawings, an elastic layer (not shown) may be further formed on an inner side surface of the front cover 210 so that the front cover 210 can be in tight contact with the enclosure 200 with elasticity.

The rear part of the electronic device 100 is disposed to protrude from the rear face of the enclosure 200 through the opening 210 as shown in FIG. 4.

A plurality of brackets 300 according to the exemplary embodiment of the present disclosure is disposed such that the periphery of the rear part of the electronic device 100 are in tight contact with the vicinity of the opening 210 at the rear face of the enclosure 200.

In addition, in the rear face of the enclosure 200, a supporting region is formed, which is brought into tight contact with the end of the second portion 312 and pressed.

According to the exemplary embodiment of the present disclosure, the electronic device 100 may be installed in tight contact with the enclosure 200 by pressing the front cover 110 disposed at the front face of the enclosure 200 and the brackets 130 disposed at the rear face of the enclosure 200 against each other when the electronic device 100 is located in the opening 210.

Subsequently, the configuration of the brackets 300 having the above-described functions will be described.

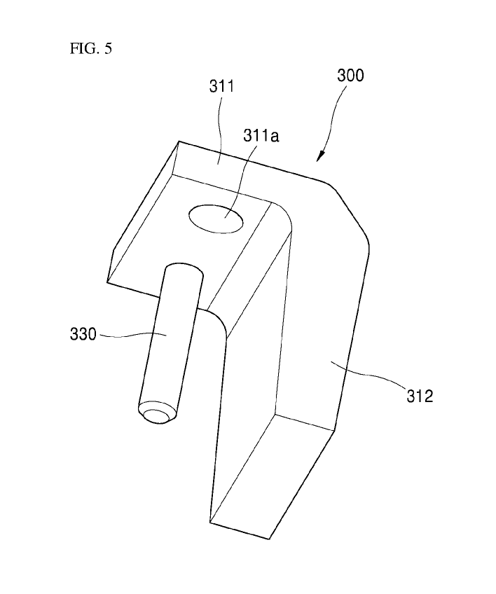

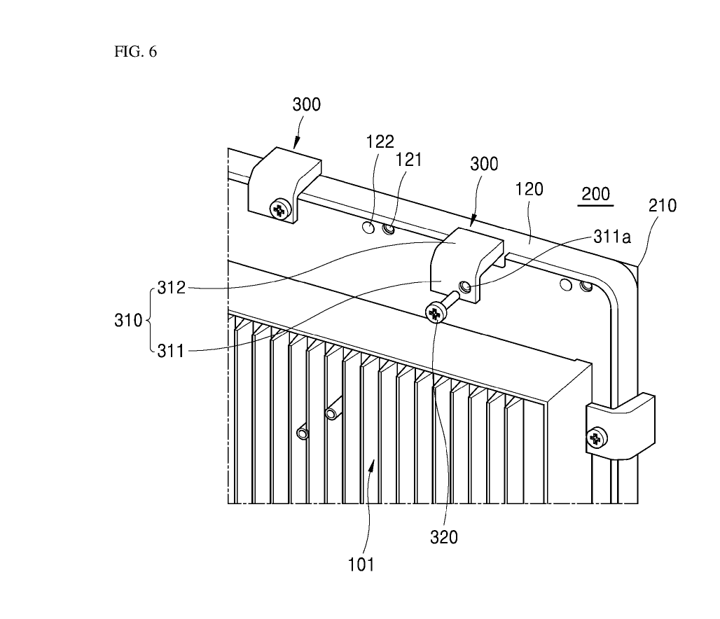

FIG. 5 is a perspective view showing a configuration of a bracket for fixing an electronic device according to an exemplary embodiment of the present disclosure. FIG. 6 is a perspective view showing the rear part 101 of the electronic device where the brackets are disposed.

Referring to FIG. 5, the bracket 300 according to the exemplary embodiment of the present disclosure may include a bracket body 310 having a first portion 311 and a second portion 312, and a coupling member 320.

The first portion 311 is disposed in tight contact with the rear part 101 of the electronic device 100.

The second portion 312 is bent from the end of the first portion 311 and disposed to be in tight contact with the side surface of the periphery 120 of the rear part of the electronic device 100.

Preferably, the angle between the first and second portions 311 and 312 may be equal to the angle between the rear face and the top face of the periphery 120 of the rear part of the electronic device 100.

In addition, an end of the second portion 312 is in contact with the rear face of the enclosure 200.

A through hole 311a is formed in the first portion 311, via which the coupling member 320 passes.

Preferably, the coupling member 320 is a screw bolt.

Fastening holes 121 are formed along the periphery of the rear part of the electronic device 100 such that they are spaced apart from one another.

The fastening hole 121 is aligned with the through-hole 311a, so that the coupling member 320 may be inserted through the through hole 311a and the fastening hole 121.

By doing so, the first portion 311 can be fixed to the periphery 120 of the rear part of the electronic device 100.

The first and second portions 311 and 312 may move forward and backward depending on the degree at which the coupling member 320 is fastened.

Specifically, when the coupling member 320 is rotated in the direction that it is fastened as being inserted into the through hole 311a, the second portion 312 moves toward the rear face of the enclosure 200.

On the contrary, when the coupling member 320 is rotated in the opposite direction that it is released as being inserted into the through hole 311a, the second portion 312 moves away from the rear face of the enclosure 200.

A guide rod 330 is formed at the first portion 311, which has a predetermined length and protrudes from it.

Preferably, a guide hole 122 may be formed in the periphery 120 of the rear part of the electronic device 100.

The shape of the guide rod 330 may be a circular bar, and the shape of the guide hole 122 may be a cylindrical hole.

Accordingly, the first portion 311 moves back and forth as the guide rod 330 is inserted into the guide hole 122, and thus the movement is guided so that it is possible to prevent the first portion 311 from deviating.

Preferably, the guide hole 122 having the shape conforming to the cross section of the guide rod 330.

Next, a mechanism for fixing an electronic device that employing the above-described brackets will be described.

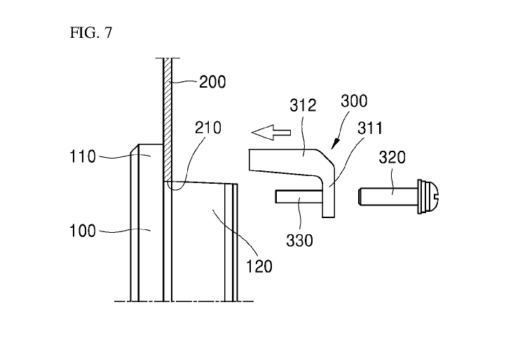

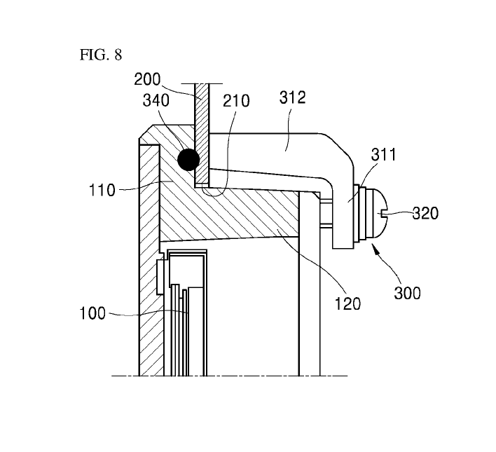

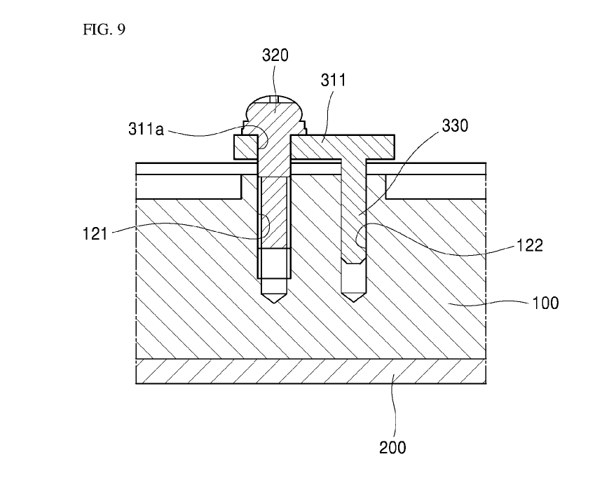

FIG. 7 is a view showing the electronic device fixed to the enclosure by using the bracket according to the exemplary embodiment of the present disclosure. FIG. 8 is a view showing the elastic member interposed between the front cover and the enclosure according to the exemplary embodiment of the present disclosure. FIG. 9 is a cross-sectional view showing the bracket when it is installed.

The electronic device 100 may be located in the opening 210 formed in the enclosure 200 as shown in FIGS. 3 and 4.

The front cover 110 is in contact with the front face of the enclosure 200, and the rear part of the electronic device 100 protrudes along the rear face of the enclosure 200.

The plurality of brackets 300 according to the exemplary embodiment of the present disclosure is disposed.

A process of installing the brackets 300 will be described with reference to FIGS. 6 to 9.

The first portion 311 of each of the brackets 300 is fastened by fastening the coupling member 320 inserted into the through hole 311a into the fastening hole 121 formed in the periphery of the rear part of the electronic device 100.

In addition, the second portion 312 is located on the outer surface of the periphery 120 of the rear part of the electronic device 100.

At this time, an end of the second portion 312 faces the rear face of the enclosure 200.

Subsequently, the coupling member 320 is rotated to be gradually fastened into the fastening hole 121.

Accordingly, the second portion 312 is moved close to the rear face of the enclosure 200 at the outer side surface of the periphery of the rear part 120 of the electronic device 200, thereby pressing the rear face of the enclosure 200.

In this manner, the front cover 110 and the end of the second portion 312 can be pressed against each other with the enclosure 200 therebetween, so that the electronic device 100 can be stably fixed in the opening 210.

In addition, a guide rod 330 protruding from the first portion 311 is formed. The guide rod 330 is to be inserted into a guide hole 122 formed in the periphery of the rear part 120 of the electronic device 100 so as to be movable.

Accordingly, the movement of the second portion 312 in the process of fastening the coupling member 320 as described above is guided, and thus it is possible to prevent the second portion 312 from deviating.

In addition, as shown in FIG. 8, an elastic member 340 is interposed between the front cover 110 and the enclosure 200. Accordingly, when the front cover 110 and the end of the second portion 312 are pressed against each other, with the enclosure 200 therebetween, an elastic force may be applied to increase the efficiency of the degree of contact and to absorb external impact.

In addition, since the elastic member 340 is interposed, it is possible to prevent foreign matter from being introduced into the opening 210 where the electronic device 100 is fixed.

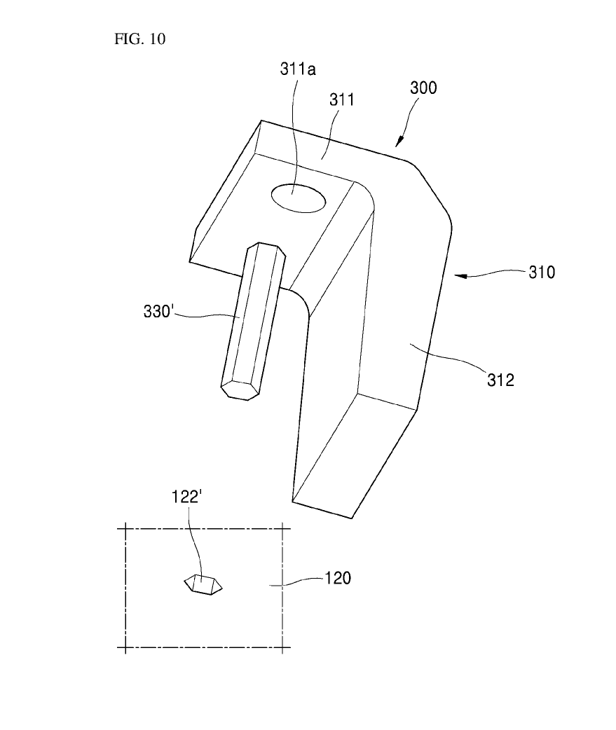

FIG. 10 is a view showing another example of the guide member.

Referring to FIG. 10, the longitudinal section of the guide rod 330′ according to this example may have a polygonal shape.

That is, the guide rod 330′ according to this example may have a polygonal shape and may be formed as a rod having a certain length.

In addition, a guide hole 122′ formed in the periphery 120 of the rear part of the electronic device 100 may also be formed as a polygonal groove.

Therefore, the guide rod 330′ formed in a polygonal shape may move back and forth as being inserted into the polygonal guide hole 122′.

As the polygonal guide rod 330′ and guide hole 122′ are coupled to each other, it is possible to prevent rotation of the guide rod 330′ while it is moving in the guide hole 122′.

Therefore, the guide rod 330′ is not rotated in the process of bringing the second portion 312 into contact with the rear face of the enclosure 200, and thus it is possible to effectively prevent a problem that the second portion 312 deviates along the rotation direction.

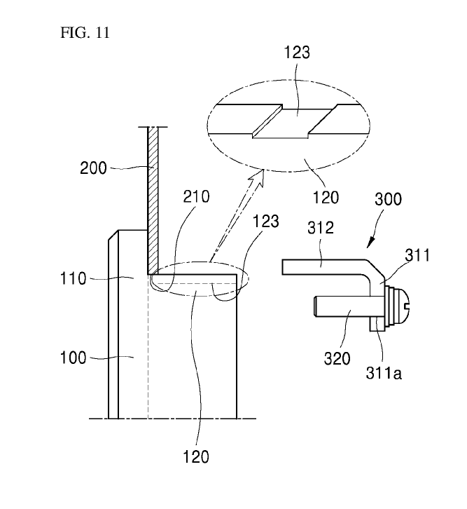

FIG. 11 is a view showing an example of a guide groove formed in an outer side surface of the periphery of the rear part of the electronic device.

Referring to FIG. 11, according to this exemplary embodiment, a guide groove 123 may be formed on the outer surface of the periphery of the rear part 120 of the electronic device 100.

Preferably, the width of the guide groove 123 may be substantially equal to the width of the second portion 312.

Preferably, the guide groove 123 may be formed along the moving direction of the second portion 312.

Accordingly, the second portion 312 is moved along the guide groove 123 in the process of bringing the second portion 312 into contact with the enclosure 200, so that it is possible to prevent the deviation of the moving path.

In addition, when an external impact is applied to the enclosure 200, it is possible to prevent that the end portion of the second portion 312 in contact with the rear face of the enclosure 200 deviates.

According to the above-described configuration and operation, the bracket according to the exemplary embodiments of the present disclosure can form a stable fixing force, so that the electronic device can be fixed to the enclosure.

While the present disclosure has been described in connection with the exemplary embodiments of the brackets for fixing an electronic device, it is to be appreciated that various modifications and variations can be made without departing from the scope of the present disclosure.

Accordingly, the scope of the present disclosure is not construed as being limited to the above-described embodiments but is defined by the appended claims as well as equivalents thereto.

Therefore, it should be understood that the above-mentioned embodiments are not restrictive but are illustrative in all aspects. It should be understood that the drawings and the detailed description are not intended to limit the present disclosure to the particular forms disclosed herein, but on the contrary, the intention is to cover all modifications, equivalents, and alternatives falling within the spirit and scope of the present disclosure as defined by the appended claims.

What is claimed is:

1. A bracket for fixing an electronic device, wherein the electronic device is accommodated in an opening formed in an enclosure and has a front cover in tight contact with a front face of the enclosure in vicinity of the opening, the bracket comprising:
a bracket body that has a first end supporting a rear part of the electronic device and a second end in contact with a periphery of the rear part of the electronic device; and
a coupling member disposed in the bracket body to press the front cover and the second end of the bracket body against each other from the front and rear faces of the enclosure, to fix the electronic device.

2. The bracket of claim 1, wherein the bracket body comprises
a first portion having a fastening hole through which the coupling member passes; and a second portion bent from an end of the first portion so as to surround the periphery of the rear part of the electronic device,
wherein the coupling member is coupled with the periphery of the rear part of the electronic device by being screwed, and an end of the second portion forms a supporting region in tight contact with the rear face of the enclosure near the opening.

3. The bracket of claim 2, wherein a guide hole is formed in the periphery of the rear part of the electronic device, and
wherein a guide rod protrudes from the first portion, such that it is inserted into the guide hole to guide movement.

4. The bracket of claim 3, wherein the guide hole is formed in a shape conforming to the guide rod, and
wherein a longitudinal section of the guide rod is formed in a polygonal shape.

5. The bracket of claim 2, wherein a guide groove for guiding movement of the second portion is further formed in the periphery of the rear part of the electronic device.

6. The bracket of claim 3, wherein an elastic member is interposed between the front cover and the enclosure.

7. A mechanism for fixing an electronic device by using the bracket according to claim 1.
